(19) United States
(12) Patent Application Publication
(10) Pub. No.: US 2024/0034616 A1
(43) Pub. Date: Feb. 1, 2024

(54) ELECTROMECHANICAL MICROSYSTEM

(71) Applicant: COMMISSARIAT A L'ENERGIE ATOMIQUE ET AUX ENERGIES ALTERNATIVES, Paris (FR)

(72) Inventors: Laurent MOLLARD, Grenoble Cedex 09 (FR); Stéphane NICOLAS, Grenoble Cedex 09 (FR); Damien SAINT-PATRICE, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/258,547

(22) PCT Filed: Dec. 17, 2021
(86) PCT No.: PCT/EP2021/086648

§ 371 Date: Jun. 20, 2023

(30) Foreign Application Priority Data
Dec. 21, 2020 (FR) 20 13820

(51) Int. Cl. B81B 3/00; G02B 26/08; B81C 1/00

(52) U.S. Cl. CPC B81B 3/0051; G02B 26/0858; B81C 1/00341; B81B 2201/042; B81B 2203/0127; B81C 2201/0132

(57) ABSTRACT

The invention relates to an electromechanical microsystem comprising an electromechanical transducer, a deformable membrane and a cavity hermetically containing a deformable medium, preserving a constant volume under the action of an external pressure change. The deformable membrane forms a wall of the cavity and has at least one free zone being deformed. The electromechanical transducer is configured, such that its movement is a function of said external pressure change, and conversely. The free zone engages with an external member, such that its deformation induces, or is induced by, a movement of the external member. The electromechanical microsystem is thus capable of moving the external member or of capturing a movement of this member.

### TECHNICAL FIELD OF THE INVENTION

The present invention relates to the field of electromechanical microsystems. It has, for example, a particularly advantageous application in the actuation or the movement of objects, including over relatively large distances. The invention also has an application in the field of contact detection. It can thus be implemented to produce sensors.

### STATE OF THE ART

In varied applications, there can be a need to move microscopic, even nanoscopic objects, and/or a need to capture movements of such objects. There are microsystems which enable this.

When these microsystems are actuators, their performances are evaluated in particular on the following parameters: the amplitude of the movement, the force used and the accuracy of the movement generated. When these microsystems are sensors, their performances are evaluated in particular on the following parameters: the capacity to capture a movement over a significant amplitude.

Moreover, whether the microsystems are actuators or sensors, it is sought that they offer good performances in terms of bulk, energy consumption and capacity to work in frequency.

All the known solutions have low performances for at least one of these parameters. Generally, the current microsystems have performances which are insufficiently satisfactory for a combination of these parameters.

An aim of the present invention is to propose an electromechanical microsystem which has improved performances with respect to the current solutions, at least for one of the parameters mentioned above, or which has a better compromise relating to at least two of the abovementioned parameters.

Other aims, features and advantages of the present invention will appear upon examining the following description and the accompanying drawings. It is understood that other advantages can be incorporated.

### SUMMARY OF THE INVENTION

To achieve this aim, according to an embodiment, an electromechanical microsystem is provided, comprising:
a. at least one electromechanical transducer comprising a part which is moveable between a non-urged balanced position, and an urged non-balanced position,
b. at least one deformable membrane,
c. a deformable cavity delimited by walls.

At least one part of the deformable membrane forms at least one part of a first wall taken from among said walls of the cavity.

The cavity is configured to hermetically contain a deformable medium specific to preserving a substantially constant volume under the action of an external pressure change exerted on the deformable medium through one of the walls of the cavity.

The moveable part of the electromechanical transducer is configured such that its movement is a function of said external pressure change or conversely that its movement induces an external pressure change.

Said at least one part of the deformable membrane has at least one free zone to be deformed according to said external pressure change.

The electromechanical microsystem is further such that said at least free zone is configured to engage with an external member such that its deformation induces, or is induced by, a movement of the external member.

Furthermore, a surface of the free zone of the deformable membrane is twice less than a surface of the moveable part of the electromechanical transducer.

The electromechanical microsystem such as introduced above is thus capable of moving the external member or of capturing a movement of this member, and this, by having, in an easily adjustable manner according to the targeted applications, a sufficient capacity in terms of movement amplitude and/or a sufficient capacity in terms of force used and/or a movement capturing capacity over a sufficient amplitude and/or a sufficient capacity to work in frequency and/or a size compatible with the targeted applications, and/or a reduced energy consumption.

Moreover, the solution proposed makes it possible for the electromechanical microsystem to form a so-called long-travel actuator, i.e. typically enabling the movement of the external member over a stroke length of at least 30 μm, even 100 μm. Likewise, a solution proposed makes it possible for the electromechanical microsystem to form a so-called long-travel sensor, typically enabling to capture a movement, the amplitude of which is at least 30 μm, even 100 μm.

Optionally, the free zone of the deformable membrane is configured to engage with the external member via a finger, also called pin, fixed on said free zone. Preferably, the pin is fixed in contact with said free zone, and more specifically in contact with an external face of the free zone. Even more preferably, the pin is formed at the same time as the free zone of the deformable membrane is exposed. According to the latter preference, it is advantageously simpler to obtain the pin, and any risk of tearing the deformable membrane is thus avoided, contrary to a case wherein the pin would be deposited, and more specifically mounted, on the deformable membrane.

Another aspect of the invention relates to an opto-electromechanical system or microsystem comprising at least one electromechanical microsystem such as introduced above and at least one optical microsystem.

Another aspect of the invention relates to a method for manufacturing an electromechanical microsystem such as introduced above, comprising, even limited to, ordinary microelectronic deposition and etching steps. The electromechanical microsystem can indeed be manufactured by ordinary microelectronic means, which gives to its manufacturer all the advantages arising from the use of these means, including a large latitude in terms of sizing, adhesion energy between the different depositions, thickness of different depositions, etching extent, etc.

According to an example, the method for manufacturing the electromechanical microsystem comprises the following steps:
a. a step of forming, on a substrate, a portion at least of at least one electromechanical transducer, then
b. a step of depositing the deformable membrane, then
c. a step of forming an open cavity on the deformable membrane, then
d. a step of filling with the deformable material and of closing the cavity, and
e. a step of etching the substrate to form a front face (FAV) of the electromechanical microsystem.

### BRIEF DESCRIPTION OF THE FIGURES

The aims, objectives, as well as the features and advantages of the invention will best emerge from the detailed description of an embodiment of the latter, which is illustrated by the following accompanying drawings, wherein:

FIG. 1A is a principle diagram of a cross-sectional view of an electromechanical microsystem according to a first embodiment of the invention.

FIG. 1B is a principle diagram of a cross-sectional view of an electromechanical microsystem according to a second embodiment of the invention.

FIG. 1C represents a top view of the first and second embodiments of the invention illustrated in FIGS. 1A and 1B.

FIG. 2A schematically represents a cross-sectional view of an electromechanical microsystem according to a third embodiment of the invention.

FIG. 2B schematically represents a cross-sectional view of an electromechanical microsystem according to a fourth embodiment of the invention.

FIGS. 3A to 9A schematically represent steps of an example of a method for producing an electromechanical microsystem such as illustrated in FIG. 2A.

FIGS. 3B to 9B schematically represent steps of an example of a method for producing an electromechanical microsystem such as illustrated in FIG. 2B.

FIG. 10 schematically represents an opto-electromechanical microsystem comprising four electromechanical microsystems according to an embodiment of the invention.

FIGS. 11A and 11B each schematically represent an opto-electromechanical microsystem according to an embodiment of the invention.

The drawings are given as examples, and are not limiting of the invention. They constitute principle schematic representations intended to facilitate the understanding of the invention and are not necessarily to the scale of practical applications. In particular, the thicknesses of the different layers, walls and members illustrated are not necessarily representative of reality. Likewise, the lateral dimensions of the piezoelectric element, of the free zone of the membrane and/or of the abutments are not necessarily representative of reality, in particular when considered against one another.

### DETAILED DESCRIPTION OF THE INVENTION

Before starting a detailed review of embodiments of the invention, optional features are stated below, which can optionally be used in association or alternatively.

According to an example, the free zone is free to be elastically deformed according to said external pressure change.

The electromechanical microsystem such as introduced above, preferably has no optical element, such as a lens, in particular with a variable focal length.

When the free zone of the deformable membrane is configured to engage with the external member via a pin, the latter can have the following optional features which can optionally be used in association or alternatively.

According to an example, the pin is fixed at the centre of the free zone of the deformable membrane. In this way, it is ensured that the movement of the pin is a translation movement perpendicular to the plane wherein the wall of the cavity falls, which is partially formed by the deformable membrane, when the membrane is not deformed.

According to an example, the pin extends mainly in a longitudinal direction. When the membrane is not deformed, the longitudinal direction of the pin is substantially perpendicular to a plane (xy), wherein an external face of the membrane mainly extends when the membrane is not deformed. The pin can have a cylindrical shape. According to an alternative embodiment, the pin does not have a cylindrical shape. It can have a curved shape, for example.

According to an example, the pin has a first end by which it bears on the free zone and a second end opposite the first end.

According to an example, the pin extends between the first end and the second end, mainly in a longitudinal direction. Alternatively, the pin has a curved shape or extends in several different directions.

According to an example, the free zone has a central portion extending from a centre of the free zone and a peripheral portion disposed around the central portion. For example, the pin bears by its first end on the central portion of the free zone.

The pin can be configured to engage with the external member by way of an integral guide of the external member, so as to enable an automatic positioning of the external member on the pin.

According to an example, the pin is configured to be able to be integral with the external member by bonding or magnetism.

According to an example, the adherence energy of the pin on the free zone of the deformable membrane is greater than that of the pin on the external member.

Thanks to the pin according to either of the two preceding examples, a securing, optionally removable, of the pin and of the external member is provided, which is widely adjustable in terms of retaining force.

According to an example, at least one part of the electromechanical transducer forms a part of the wall of the cavity which is partially formed by the deformable membrane. The electromechanical microsystem according to this feature has a non-through structure, leaving the other walls of the cavity free, so as to be able to carry out other functions there or so as to enable them to remain inert, for an increased integration capacity, in particular in an opto-electromechanical microsystem.

According to an example, the electromechanical transducer extends, directly over the deformable membrane, i.e. that the electromechanical transducer is directly in contact with the deformable membrane. Alternatively, the electromechanical transducer extends indirectly over the deformable membrane, i.e. that at least one element or one intermediate layer is disposed between the electromechanical transducer and the deformable membrane.

According to an example, the electromechanical transducer fully surrounds the free zone of the deformable membrane.

According to a non-limiting example, the electromechanical transducer takes an annular shape, the circular centre of which defines the extent of the free zone of the deformable membrane.

The electromechanical transducer can be configured such that a movement of its moveable part from its balanced position to its unbalanced position induces an increase of the external pressure acting on the deformable medium and the deformable membrane can be configured such that an increase of external pressure acting on the deformable medium induces a deformation of the free zone of the deformable membrane tending to move the external member of the cavity away (more specifically, to move it away from the fixed wall of the cavity such as the wall opposite the wall partially formed by the membrane). The electromechanical microsystem is thus configured so as to induce a movement of the external member in a first direction, corresponding to a moving away of the external member with respect to the cavity.

Alternatively to the preceding feature, the electromechanical transducer can be configured such that a movement of its moveable part from its balanced position to its unbalanced position induces a decrease of the external pressure acting on the deformable medium and the deformable membrane can be configured such that a decrease of the external pressure acting on the deformable medium induces a deformation of the free zone of the deformable membrane tending to move the external member of the cavity closer (more specifically, to move it closer to a fixed wall of the cavity such as the wall opposite the wall partially formed by the membrane). The electromechanical microsystem is thus configured so as to induce a movement of the external member in a second direction, this second direction tending to move the external member of the cavity closer.

At least the moveable part of the electromechanical transducer can be integral with a zone of the deformable membrane adjacent to the free zone of the deformable membrane, such that a movement of the moveable part of the electromechanical transducer, including a movement inducing the moving closer of the external member with respect to the cavity, induces a corresponding movement of said zone of the deformable membrane adjacent to its free zone.

The electromechanical microsystem such as introduced above can further comprise a plurality of deformable membranes and/or a plurality of free zones per deformable membrane and/or a plurality of electromechanical transducers.

The moveable part of the electromechanical transducer can have a surface at least twice greater than a surface of the free zone of the deformable membrane. Preferably, the surface of the moveable parts of the transducers is at least 5 times, even 10 times, even 20 times greater than the surface of the free zone 121 of the deformable membrane, even than the surface of the free zones of the deformable membrane. The larger the surface of the transducer is with respect to the surface of the free zone 121 of the deformable membrane, even to the surface of the free zones of the deformable membrane, the greater the deformation amplitude will be.

The deformable membrane is preferably configured such that its free zone is capable of being deformed with an amplitude of at least 50 μm, even of at least 100 μm, even of at least 1000 μm, in a direction perpendicular to the plane wherein it mainly extends, when it is at rest. Without tearing and/or without significant wear, the electromechanical microsystem thus offers the capacity to satisfy numerous and various applications requiring a long travel, the latter being defined, if necessary, by technical field in question.

The electromechanical microsystem can further comprise at least one lateral abutment configured to guide the movement of the external member and/or to engage a non-moveable part of an electromechanical transducer. According to an optional example, the lateral abutment is supported by the wall of the cavity which is partially formed by the deformable membrane. According to an optional example, said at least one lateral abutment extends opposite the cavity.

It is thus possible to:
a. limit, in a controlled, reliable and reproducible manner, the inclination of the pin during the movement of the moveable part of the electromechanical transducer, and/or
b. enable a self-positioning of the external member relative to the free zone of the deformable membrane, and/or
c. protect the deformable membrane, and more specifically, its free zone, in particular, a possible tearing, during a transfer or a bonding of the external member.

When the free zone of the deformable membrane is configured to engage with the external member via a pin fixed on said free zone, the electromechanical microsystem can further have the following optional features which can optionally be used in association or alternatively.

The pin can extend from the free zone of the deformable membrane beyond said at least one lateral abutment.

Alternatively, the pin can extend from the free zone of the deformable membrane below said at least one lateral abutment.

The electromechanical microsystem according to either of the two preceding features offers a satisfactory adaptation capacity to a wide variety of external members and applications.

The electromechanical microsystem can further comprise a so-called bottom abutment supported by the wall of the cavity opposite the free zone of the deformable membrane, said bottom abutment extending into the cavity towards the free zone. It has a shape and dimensions configured to limit the deformation of the free zone of the deformable membrane so as to protect the deformable membrane, and more specifically its free zone, in particular, a possible tearing, during a transfer or a bonding of the external member. Moreover, the so-called bottom abutment can be shaped to limit the contact surface between the membrane and the wall of the cavity opposite the free zone of the deformable membrane. Alternatively or cumulatively, the bottom abutment can be shaped so as to limit the contact surface between the membrane and the wall of the cavity opposite the free zone of the deformable membrane. This makes it possible to avoid the membrane adhering to this wall.

The electromechanical transducer can be a piezoelectric transducer, preferably comprising a PZT-based piezoelectric material.

The electromechanical transducer can be a static working transducer.

Alternatively or complementarily, the electromechanical transducer can be a vibration working transducer at at least one resonance frequency, said at least one resonance frequency preferably being less than 100 kHz, and also more preferably less than 1 kHz.

The deformable medium hermetically container in the cavity can comprise at least one fluid, preferably liquid. The fluid preferably has a viscosity of around 100cSt at ambient temperature and pressure (1cSt=10⁻⁶ m²/s).

According to a non-limiting example of an embodiment, the fluid has a compressibility of between 10⁻⁹ and 10⁻¹⁰ Pa⁻¹ at 20° C., for example of around 10⁻¹⁰ Pa⁻¹ at 20° C., without these values being limiting.

Said at least one optical microsystem of the opto-electromechanical system such as introduced above can comprise at least one mirror, also called micro-mirror, preferably silicon-based.

According to an example, the opto-electromechanical system is configured such that the movement of the moveable part of the electromechanical transducer causes a movement of the at least one mirror.

Alternatively or complementarily, the opto-electromechanical system can comprise a plurality of electromechanical microsystems, each having a free zone arranged opposite a part of one same optical microsystem, such as a mirror. Preferably, the electromechanical microsystem engages with the mirror at a zone which is not at the centre of the mirror, but for example, in the corner of the mirror. An opto-electromechanical system or microsystem is thus obtained, benefiting from a wide adaptation capacity of its optical orientation.

By “electromechanical microsystem”, this means a system comprising at least one mechanical element and at least one electromechanical transducer made on a micrometric scale with microelectronic means. The mechanical element can be moved (actuated) thanks to a force generated by the electromechanical transducer. The latter can be supplied by electrical voltages produced with neighbouring electronic circuits. Alternatively or complementarily, the electromechanical transducer can capture a movement of the mechanical element; the electromechanical microsystem thus plays the role of a sensor.

A “microsystem” is a system, the external dimensions of which are less than 1 centimetre (10⁻² metres) and preferably than 1 millimetre (10⁻³ metres).

Most often, an electromechanical transducer plays a role of an interface between the mechanical and electrical fields. However, in this case, by “electromechanical transducer”, this means both a piezoelectric transducer and a thermal transducer, the latter playing a role of an interface between the mechanical and thermal fields. An electromechanical transducer can comprise a moveable part between a non-urged balanced position, and an urged unbalanced position. When the transducer is piezoelectric, the urging is of an electrical nature. When the transducer is thermal, the urging is of a thermal nature.

When the centre of the cavity is mentioned, this centre is defined geometrically by considering as the centre of a cavity having a non-deformed free zone of the deformable membrane.

By “less than” and “greater than”, this means “less than or equal to” and “greater than or equal to”, respectively. Equality is excluded by using the terms “strictly less than” and “strictly greater than”.

By a parameter “substantially equal to/greater than/less than” a given value, this means that this parameter is equal to/greater than/less than the given value, plus or minus 20%, even 10%, of this value. By a parameter “substantially between” two given values, this means that this parameter is, as a minimum, equal to the smallest given value, plus or minus 20%, even 10%, of this value, and, as a maximum, equal to the largest given value, plus or minus 20%, even 10%, of this value.

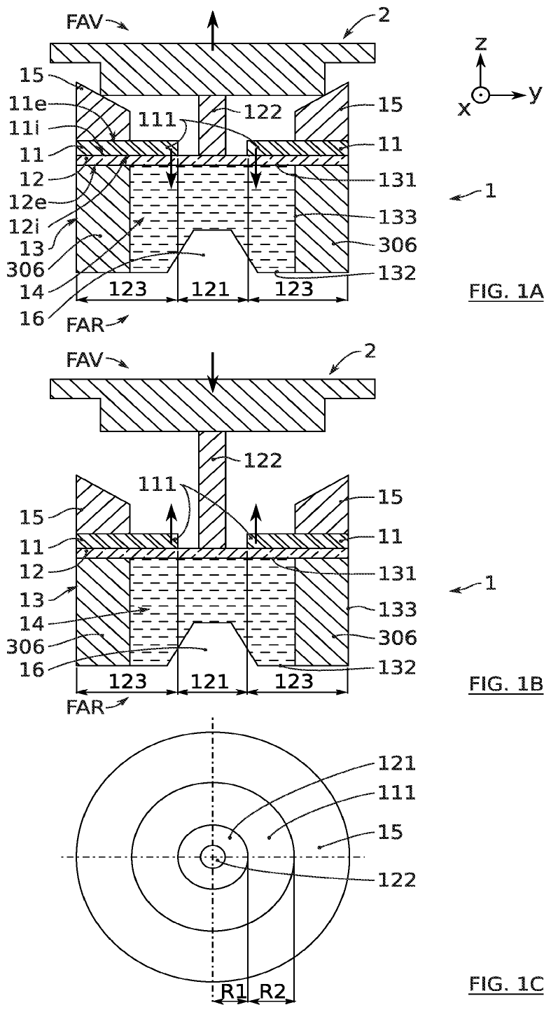

FIGS. 1A and 1B are principle diagrams of a cross-sectional view or of a cross-section of an electromechanical microsystem 1 according to the first and second embodiments of the invention. In each of the FIGS. 1A and 1B, an electromechanical transducer 11, a deformable membrane 12 and a cavity 13 are illustrated, configured to hermetically contain a deformable medium 14.

Each of these principle diagrams can also represent a symmetrical structure of rotation or revolution about a perpendicular axis and centred with respect to the cross-section of the deformable membrane such as illustrated, that a structure extending, for example in a substantially invariant manner, perpendicular to the cross-sectional view illustrated and symmetrically with respect to a plane perpendicular and centred with respect to the cross-section of the deformable membrane such as illustrated.

Before describing the different embodiments of the invention illustrated in the accompanying figures further, it is noted that each of these illustrations schematically represent an embodiment of the electromechanical microsystem according to the invention, which has a non-through structure. More specifically, in the different embodiments illustrated, the electromechanical transducer 11 and the deformable membrane 12 are both located on the front face FAV of the electromechanical microsystem 1. This type of structure is particularly advantageous insofar as the rear face FAR of the electromechanical microsystem 1 can only passively contribute, and in particular without being deformed, to the actuator and/or sensor function of the electromechanical microsystem 1. More specifically, the rear face FAR of an electromechanical microsystem 1 with non-through structure according to the invention can, in particular, constitute a face by which the electromechanical microsystem 1 can be easily mounted on a support (referenced 32 in FIGS. 11A and 11B) and/or can constitute a face by which the electromechanical microsystem can easily be further functionalised.

However, the invention is not limited to non-through structure electromechanical microsystems. In its widest acceptance, the invention also relates to so-called through structure electromechanical microsystems 1, wherein the electromechanical transducer 11 and the deformable membrane 12 are arranged on walls which are distinct from one another from the cavity 13, that these walls are adjacent to one another or opposite one another.

The electromechanical transducer 11 comprises at least one moveable part 111. The latter is configured to move or be moved between at least two positions. A first of these positions is a balanced position, reached and preserved when the electromechanical transducer 11 is not urged, whether, for example, by an electrical current supplying it or by a force stressing its moveable part outside of its balanced position. A second position of the moveable part 111 of the electromechanical transducer 11 is reached when the electromechanical transducer 11 is urged, whether, for example, by electrical current supplying it or by a force stressing its moveable part outside of its balanced position. The electromechanical transducer 11 can be held in either of the first and second positions described above, and thus have a binary behaviour, or can further be held in any intermediate position between its balanced position and its position of greatest deformation, or of greatest deflection, with respect to the balance.

In the example illustrated, when the electromechanical transducer 11 is not urged, its moveable part 111 mainly extends into a plane parallel to the plane xy of the orthogonal system xyz illustrated in FIG. 1A.

The electromechanical transducer 11 is preferably a piezoelectric transducer. More specifically, the electromechanical transducer 11 comprises at least one piezoelectric material mechanically coupled with another element, qualified as a support or beam. The term of “beam” does not limit at all the shape of this element.

In a known manner, a piezoelectric material has, as a property, of stressing when an electric field is applied to it. By being stressed, it is deformed. Mechanically associated to the support, the piezoelectric material drives the support with it and thus moves the latter. The zone of the support which can be moved corresponds to the moveable part 111. It is this movement property which is used to form an actuator.

Likewise, under the action of a mechanical stress, a piezoelectric material is electrically polarised. Thus, when the support is moved, it deforms the piezoelectric material which induces an electrical current. It is this property which is used to form a sensor.

It therefore emerges from this example of an embodiment of the electromechanical transducer 11, but this remains potentially true for each of the other embodiments considered of the electromechanical transducer 11, that the electromechanical microsystem 1 according to the invention can operate as actuator and/or sensor. As an actuator, it can make it possible to move an external member 2 upwards, as illustrated in FIG. 1A, or downwards, as illustrated in FIG. 1B. As a sensor, it can make it possible to capture a movement, in particular a vertical movement, of the external member 2. Below, for reasons of simplicity, the electromechanical microsystem 1 is mainly described as an actuator, without however excluding its capacity to ensure, alternatively or complementarily, a sensor function.

The electromechanical transducer 11 is even more preferably a piezoelectric transducer comprising a PZT-based piezoelectric material (lead zirconate titanate). In this case, the moveable part 111 of the electromechanical transducer 11 is capable under urging of moving with a more significant movement (due to the piezoelectric coefficient d31) than with a good number of other piezoelectric materials. However, PZT being a ferroelectric material, such a piezoelectric transducer operates preferably in one single actuation direction (movement in one single direction of its moveable part 111), whatever the polarity of its electrical supply, while a piezoelectric transducer with the basis of a non-ferromagnetic material can preferably operate in both directions (movement in two opposite directions of its moveable part 111). Alternatively or complementarily, the electromechanical transducer 11 can be a (non-ferroelectric) piezoelectric transducer with the basis of a material specific to enabling its moveable part 111 to move in opposite directions relative to its balanced position, for example, according to the polarity of its electrical supply. Such a material is, for example, an aluminium nitride (AlN)-based material.

Alternatively or complementarily, the electromechanical transducer 11 can be or comprise a thermal transducer.

The deformable membrane 12 can be with the basis of a polymer, and is preferably PDMS(polydimethylsiloxane)-based. The properties of the deformable membrane 12, in particular its thickness, its surface and its shape, can be configured to give to the deformable membrane 12, and more specifically to a zone 121 of this membrane, which is free to be deformed, an expected tearing capacity, in particular, according to the targeted application.

The cavity 13 such as illustrated, in particular, in FIGS. 1A and 1B has more specifically, walls 131, 132, 133 hermetically containing the deformable medium 14. In the examples illustrated, the wall 132 of the cavity 13 constitutes the rear face FAR of the electromechanical microsystem 1. The wall 131 opposite the wall 132 is formed at least partially by at least one part of the deformable membrane 12. Thus, the wall 131 is deformable. The wall 131 is referenced below as first wall. It is located at the front face FAV of the electromechanical microsystem 1. At least one side wall 133 joins together the walls 131 and 132. It will be noted that the hermeticity of the cavity 13 can require that the deformable membrane 12 is itself impermeable, or made impermeable, in particular at its free zone 121.

It will also be noted that, to ensure the hermeticity of the cavity 13 more easily:
a. the first wall 131 of the cavity is preferably fully formed or covered by at least the deformable membrane 12, and/or
b. the electromechanical transducer 11 extends from its whole extent over the deformable membrane 12, by being in direct or indirect contact with it.

Preferably, the walls 132, 133 remain fixed when the membrane 12 is deformed.

The deformable medium 14 is itself specific to preserving a substantially constant volume under the action of an external pressure change. In other words, this can be an incompressible or slightly compressible medium, the deformation of which preferably requires little energy. This is, for example, a liquid.

Due to at least one part of the wall 131 of the cavity 13 is formed by at least one part of the deformable membrane 12, it is understood that any external pressure change exerted on the deformable medium 14 can be compensated for by a deformation, substantially proportional, of the deformable membrane 12, and more specifically of its free zone 121, and/or by a movement of the moveable part 111 of the electromechanical transducer 11. When the transducer is urged, this compensation is more specifically linked to a conversion of the external pressure change exerted on the deformable medium 14 in a tearing of the deformable membrane 12 or a relaxation of the deformable membrane 12 already torn. It is reminded that the deformable medium 14 is incompressible and that these stresses are therefore carried out with a preservation of the volume of the cavity 13. It is understood that, being concerned about reproducibility of the actuation or of the capturing of the movement that the electromechanical microsystem 1 according to the invention offers, it is preferable that any deformation of the deformable membrane 12 is elastic, and not plastic, to guarantee the return into the same state of lesser tearing, or of maximum relaxation, of the deformable membrane 12 each time that it is no longer stressed.

The deformable medium 14 can more specifically comprise at least one fluid, preferably liquid. The parameters of the liquid will be adapted according to the targeted applications. It is thus ensured that any external pressure change exerted on the deformable medium 14 induces a substantially proportional deformation of the free zone 121 of the deformable membrane 12. The fluid can be constituted, or with the basis, of a liquid, such as oil or can be constituted, or with the basis, of a polymer. According to an example, the fluid is glycerine-based, or is constituted of glycerine. It is thus ensured that, in addition to a substantially proportional deformation of the membrane 12, of the capacity of the deformable medium 14 to occupy, in particular, the volume created by tearing of the free zone 121 of the deformable membrane 12 opposite the centre of the cavity 13.

It is understood from the above, that the electromechanical microsystem 1 is configured, such that the movement of the electromechanical transducer 1 is a function of the external pressure change exerted on the deformable medium 14, to perform the function of an actuator of the electromechanical microsystem 1, and conversely, to perform the function of a sensor of the electromechanical microsystem 1. More specifically, when the electromechanical microsystem 1 plays the role of an actuator, the electromechanical transducer 11 is urged so as to exert an external pressure change on the deformable medium 14 and through that, induce the deformation of the deformable membrane 12. Conversely, when the electromechanical microsystem 1 plays the role of a sensor, the deformation of the membrane 12 exerts an external pressure change on the deformable medium 14 which induces a movement of the moveable part 111 of the electromechanical transducer 11.

As illustrated in each of FIGS. 1A and 1B, the electromechanical microsystem 1 is such that the free zone 121 of the deformable membrane 12 is configured to engage with an external member 2. In this way, the deformation of the free zone 121 induces, or is induced by, a movement of the external member 2. It is therefore by way of the free zone 121 of the deformable membrane 12 that the electromechanical microsystem 1 moves the external member 2 or captures a movement of the external member 2. Thus, when the electromechanical microsystem 1 plays the role of an actuator, the activation of the electromechanical transducer 11 deforms the membrane 12 which moves the member 2. Conversely, when the electromechanical microsystem 1 plays the role of a sensor, a bearing of an external member 2 on the membrane 12 or a traction of the membrane 12 by an external member 2 deforms the membrane 12, which moves the electromechanical transducer 11 then ultimately generates a signal. Such that the signal generated can be a function of the movement of the external member 2, and in particular, of its movement amplitude, it is preferable that the surface of the free zone 121 is greater than the surface of the moveable part 111 of the electromechanical transducer 11, which is in contact with the deformable membrane 12.

More specifically, the engagement between the free zone 121 of the deformable membrane 12 and the external member 2 can be achieved via a finger, also called pin 122, which is fixed on the free zone 121. The terms “finger” and “pin” can be switched. The term “pin” is not limited to the parts of constant cross-section and a fortiori to the cylindrical parts.

As illustrated in each of the FIGS. 1A and 1B, the pin 122 can be more specifically fixed to the centre of the free zone 121 of the deformable membrane 12, or more generally, symmetrically with respect to the extent of the free zone 121 of the deformable membrane 12. In this way, the pin 122 is moved, by the elastic deformation of the free zone 121, in a substantially vertical controlled direction, and is not or is slightly inclined with respect to the vertical during its movements. The lateral travel of the pin 122 is thus advantageously limited.

Complementarily or alternatively, the external member 2 can be structured so as to comprise a guide by which the external member 2 is intended to engage with the pin 122. This guide can itself also contribute to opposing an inclination of the pin 122 during its movement. It will be seen below that the limitations thus reached in terms of lateral travel of the pin 122 can also be reinforced by the presence of at least one lateral abutment 15 extending from a part of the wall 131 located outside of the free zone 121 of the deformable membrane 12.

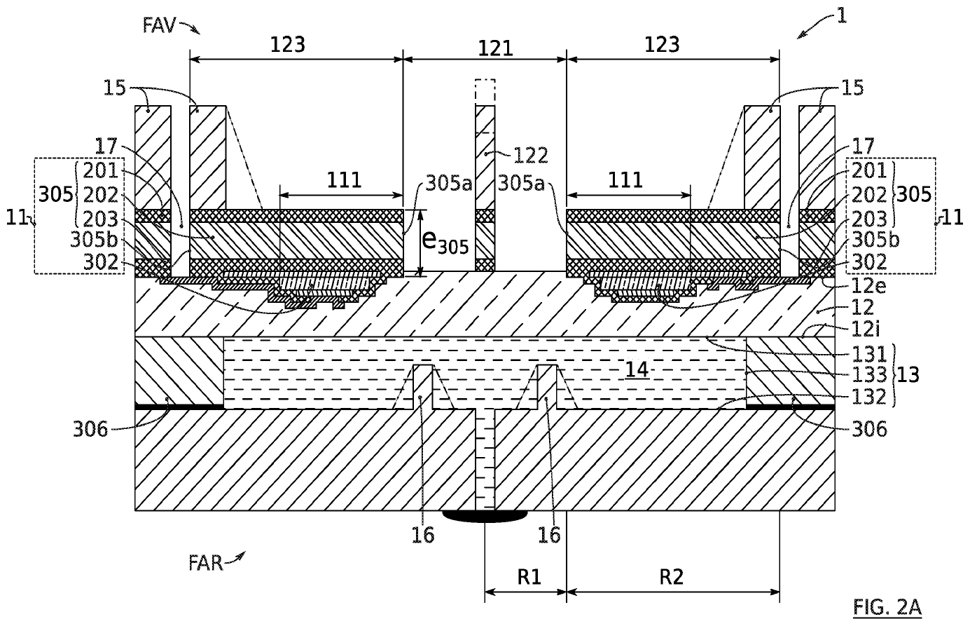

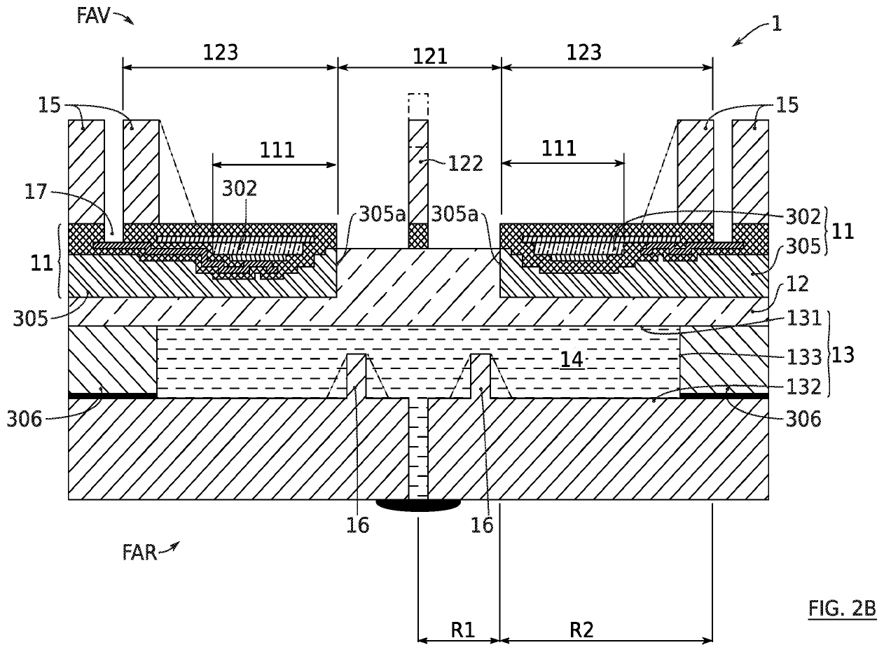

In a non-limiting manner, a bonding or a magnetising of the pin 122 on the external member 2 can make it possible to secure the pin 122 and the external member 2 together. The adherence energy of the pin 122 on the free zone 121 of the deformable membrane 12 is preferably greater than that of the pin 122 on the external member 2. It will be seen, when the methods for manufacturing the electromechanical microsystems 1 illustrated in FIGS. 2A and 2B will be described, that the adherence energy of the pin 122 on the free zone 121 can be a result from ordinary technological steps in the microelectronics field. This adherence energy could thus be estimated or measured, it is easy to obtain by bonding, for example using an ad hoc resin, or by magnetising, for example a securing, which is of an energy lower than the energy with which the pin 122 is integral with the deformable membrane 12. It is therefore understood that the securing between the pin 122 and the external member 2 is thus widely adjustable in terms of retaining force. This adjustability can make it possible, in particular, to make the securing between the pin 122 and the external member 2 removable, for example to enable one same electromechanical microsystem 1 according to the invention to be arranged successively with several external members 2, each with which it would be secured, then disconnected.

As illustrated in each of FIGS. 1A and 1B, the electromechanical transducer 11 can form a part of the first wall 131 of the cavity 13. The electromechanical transducer 11 and the deformable membrane 12 are thus placed on one side of the cavity 13. The structures having this feature are advantageously non-through as stated above.

In this non-limiting example, the membrane 12 has an internal face 12i configured to be in contact with the deformable medium 14 and an external face 12e. The internal face 12i forms a part of the first wall 131 of the cavity 13. Preferably, to easily ensure the hermeticity of the cavity 13, the internal face 12i of the membrane 12 forms the whole first wall 131 of the cavity 13. The electromechanical transducer 11, more specifically the moveable part 111 of the latter, has an internal face 11i rotated facing, and preferably in contact with the external face 12e of the membrane 12. The electromechanical transducer 11 also has an external face 11e, opposite the internal face 11i, and rotated towards the outside of the electromechanical microsystem 1. Preferably, to easily ensure the hermeticity of the cavity 13, the internal face 11i of the electromechanical transducer 11 is preferably fully in contact with the external face 12e of the membrane 12. It can be provided that one or more intermediate layers are disposed between the external face 12e of the membrane 12 and the internal face 11i of the electromechanical transducer. The electromechanical microsystem 1 is configured such that the movement of the moveable part 111 of the electromechanical transducer 11 causes a movement of the membrane 12 and therefore of the wall 131 which confines the medium 14.

It will be noted that, in each of FIGS. 1A and 1B:
a. the electromechanical transducer 11 extends over the deformable membrane 12 by defining the free zone 121 of the deformable membrane 12, and
b. the deformable membrane 12 separates the electromechanical transducer 11, preferably over its whole extent, from the deformable medium 14.

Furthermore, the electromechanical transducer 11 can advantageously be integral with the deformable membrane 12 on a zone 123 located outside of the free zone 121, and more specifically, on a zone 123 adjacent to the free zone 121, such that any movement of the moveable part 111 of the electromechanical transducer 11 induces, in particular on this zone 123, a tearing of the deformable membrane 12. Thus, in the example illustrated in FIG. 1B, when the electromechanical transducer 11 is urged so as to be moved upwards (as illustrated by the two arrows extending from the moveable part 111 of the electromechanical transducer 11), a decrease of the external pressure exerted on the deformable medium 14 is observed, which induces the tearing of the deformable membrane 12 downwards, i.e. towards the centre of the cavity 13. In this case, it is noted that this securing between the electromechanical transducer 11 and the deformable membrane 12 is only preferential for the electromechanical microsystem 1 represented in FIG. 1A, insofar as the moveable part 111 of the electromechanical transducer 11 is intended to bear on the deformable membrane 12 when the electromechanical transducer 11 is urged and/or insofar as the deformable membrane 12 naturally tends to remain in contact with the moveable part 111 of the electromechanical transducer 11 when the latter does not bear on the deformable membrane 12.

FIG. 1C illustrates the partial covering of the deformable membrane 12 by the electromechanical transducer 11. The electromechanical transducer 11 takes its shape from a ring of radial extent referenced R2 and defines a circular free zone 121 of radius referenced R1. It is noted that the electromechanical transducer 11 is not limited to an annular shape, but can take other shapes, and in particular, an oblong or oval shape, a triangular, rectangular shape, etc., defining a corresponding plurality of shapes of the free zone 121 of the deformable membrane 12. This illustration applies, in particular, to a symmetrical structure of rotation or of revolution. However, a corresponding illustration for a symmetrical structure with respect to a plane perpendicular and centred with respect to the cross-section of the free zone 121 could, at the same time, be supplied which would in particular consist of the representation of three adjacent strips two-by-two, the central strip of which would represent the free zone 121 of the deformable membrane 12, and the lateral strips of which would represent the moveable part of the electromechanical transducer(s) 11 involved.

In particular, when the partial covering of the deformable membrane 12 by the electromechanical transducer 11 is such as illustrated in FIG. 1C and that the electromechanical transducer 11 is a piezoelectric transducer comprising a PZT-based piezoelectric material, it is interesting that the moveable part 111 of the electromechanical transducer 11 has a surface at least twice larger than the free zone 121 of the deformable membrane 12. The deformable membrane 12 is subsequently configured such that its free zone 121 is capable of being deformed with an amplitude of at least 50 μm, around 100 μm, even several hundred μm. Preferably, the surface of the moveable part 111 of the electromechanical transducer 11 illustrated in FIG. 1C is at least 5 times, even 10 times, even 20 times larger than the surface of the free zone 121 of the deformable membrane 12 illustrated in the same figure. The measurements indicated above as an example correspond to a surface of the moveable part 111 of the electromechanical transducer 11, nineteen times larger than the surface of the free zone 121 of the deformable membrane 12.

Generally, the deformable membrane 12 is preferably configured, such that its free zone 121 is capable of being deformed with an amplitude of less than 1 mm.

The deformation amplitude of the free zone 121 is measured in a direction perpendicular to the plane, wherein the external face 12e of the membrane 12 mainly extends at rest.

Without tearing and/or without significant wear, the electromechanical microsystem 1 enables a hydraulic amplification of the actuation and thus offers the capacity to satisfy numerous and various applications requiring a long travel. In this context, the electromechanical microsystem 1 illustrated in FIG. 1A can be defined as an ascending long-travel actuator and the electromechanical microsystem 1 illustrated in FIG. 1B can be defined as a descending long-travel actuator.

Also, when the partial covering of the deformable membrane 12 by the electromechanical transducer 11 is such as illustrated in FIG. 1C and that the electromechanical transducer 11 is a piezoelectric transducer comprising a PZT-based piezoelectric transducer, but in reference to FIGS. 2A and 2B discussed in more detail below, the electromechanical transducer 11 can more specifically comprise a support 305, also called beam 305, and a PZT-based piezoelectric element 302, the latter being configured to induce a deflection of the support 305. The term “beam” 305 does not limit the shape of the support 305. In this example, the beam 305 forms a ring. The thickness of the piezoelectric element 302 can be substantially equal to 0.5 μm and the thickness of the beam 305 is, for example, of between a few μm and several tens of μm, for example, 5 μm.

Always, when the partial covering of the deformable membrane 12 by the electromechanical transducer 11 is such as illustrated in FIG. 1C and that the electromechanical transducer 11 is a piezoelectric transducer comprising a PZT-based piezoelectric material, the radius R1 of the free zone 121 of the deformable membrane 12 can be substantially equal to 100 μm and the radial extent R2 of the electromechanical transducer 11 (typically, its radius if it is circular) can be substantially equal to 350 μm. The references R1 and R2 are illustrated in FIG. 1C. In such a configuration, the moveable part 111 of the electromechanical transducer 11 can be moved or deflected with an amplitude, for example, substantially equal to 15 μm by being crossed by an electrical voltage, for example, substantially equal to 10V for a beam 305 thickness of around 5 μm and a PZT thickness of around 1 μm.

It must be noted that, in its balanced position, the moveable part 111 of the electromechanical transducer 11, and more generally, the electromechanical transducer 11, cannot be flat, but can, on the contrary, have a deflection, called balanced, which removes nothing, in terms of amplitude, movement capacity or deflection of the electromechanical transducer 11 electrically supplied.

The invention is not however limited to the different specific values given above, which can be widely adapted, according to the targeted application, in particular to find a compromise between tearing factor and expected deformation amplitude of the free zone 121 of the deformable membrane 12.

It is noted that, in particular when the electromechanical transducer 11 is a piezoelectric transducer, the electromechanical transducer 11 can advantageously be a vibration working transducer. Its resonance frequency is thus preferably less than 100 kHz, and even more preferably, less than 1 kHz. The vibration dynamic thus obtained can make it possible to reach greater travels than in static working, in particular by utilising the phenomenon of pertaining resonance or of decreasing the consumption of the electromechanical microsystem for a given travel.

As already mentioned above, the electromechanical microsystem 1 can further comprise one or more lateral abutments 15 supported by the first wall 131 of the cavity 13. Each lateral abutment 15 extends more specifically to the opposite of the cavity 13. For example, each lateral abutment 15 extends from a non-moveable part of the electromechanical transducer 11.

Each lateral abutment 15 can further have an action of holding in position a non-moveable part of the electromechanical transducer 11, said non-moveable part being complementary to the moveable part 111 of the electromechanical transducer 11.

Opposite at least one part of the or of each lateral abutment 15 relative to the deformable membrane 12, at least one spacer 306, such as schematically illustrated in FIGS. 1A and 1B, can extend into the cavity 13 or by constituting a part of the side wall 133 of the cavity 13. Such a spacer 306 makes it possible to sandwich, together with the abutment or each lateral abutment 15, the non-moveable part of the electromechanical transducer 11, for example on at least one part of its outer perimeter, so as to reinforce the holding in position of this non-moveable part.

For example, as illustrated in FIGS. 2A and 2B, the action of holding the non-moveable part of the electromechanical transducer 11 can more specifically be ensured by its engagement between the two lateral abutments 15, and in particular, that located towards a central part of the microsystem 1, and the spacer 306, such as illustrated in FIGS. 2A and 2B, which materialises the side wall 133 of the cavity 13; in this sense, the spacer 306 preferably extends towards the central part of the microsystem 1 at least up to the right of the surface of the lateral abutment 15 closest to the central part of the microsystem 1, equivalently to what is illustrated in FIGS. 1A and 1B.

Relative to this or these lateral abutments 15, the pin 122 can extend, opposite the cavity 13, beyond (see FIG. 1B) or below (see FIG. 1A). At least one lateral abutment 15 can also be configured to enable the guiding and the self-positioning of the external member 2 on the electromechanical microsystem 1. It also contributes to limiting, even removing, the risk of tearing of the deformable membrane 12 during the transfer of the external member 2 onto the electromechanical microsystem 1. In this case, it is noted that, depending on the extent of the external member 2, at least one lateral abutment 15 can also play the role of a top abutment limiting the moving closer of the external member 2 towards the electromechanical microsystem 1.

This particularity can also make it possible to induce a disconnection of the pin 122 and of the external member 2 from one another by pulling the pin 122 into a lower position that possibly reached by the external member 2 due to the latter abutting on the top of the lateral abutment 15. More specifically, the lateral abutment 15 has an abutment surface configured to stop the movement of the member 2. The electromechanical microsystem 1 is configured such that when the movement of the member 2 is stopped in its movement, in a given direction, by the lateral abutment 15, the pin 122 can continue its movement, in this same direction. The pin 122 is thus disconnected from the member 2.

As illustrated in each of the FIGS. 1A and 1B, the electromechanical microsystem 1 can further comprise one or more so-called bottom abutments 16 supported by the wall 132 of the cavity 13 which is opposite the wall 131 formed at least partially by the deformable membrane 12 and extending into the cavity 13 towards the free zone 121 of the membrane 12. This bottom abutment 16 preferably has a shape and dimensions configured to limit the deformation of the free zone 121 of the membrane 12 so as to protect the membrane 12, and more specifically, its free zone 121, from a possible tearing, in particular during the transfer of the external member 2 onto the electromechanical microsystem 1.

Alternatively or cumulatively, the bottom abutment 16 can be shaped so as to limit the contact surface between the membrane 12 and the wall 132 of the cavity 13 opposite the free zone 121 of the deformable membrane 12. This makes it possible to avoid the membrane 12 not adhering and not bonding to this wall 132.

Embodiments of the invention more specific than those described above are illustrated in FIGS. 2A and 2B, in which the same references as in FIGS. 1A and 1B reference the same objects.

First, it is observed there that each electromechanical transducer 11 illustrated comprises a beam 305 and a piezoelectric material 302 configured to deform the beam 305 when it is crossed by an electrical current.

A comparison between FIGS. 2A and 2B shows that the piezoelectric material 302 can be located on one side or the other of a neutral fibre of the assembly constituting the electromechanical transducer 11. It is thanks to this alternative that a ferroelectric piezoelectric material, the deformation of which is preferably independent of the polarisation of the electrical current crossing it, all the same makes it possible to deform the beam 305 in one direction or in the other.

More specifically, in FIG. 2A, the piezoelectric material 302 is located under the beam 305, and therefore under the neutral fibre of the assembly, i.e. that it is located between the beam 305 and the membrane 12. When an electrical voltage is applied on the piezoelectric material 302, it is retracted and drives the beam 305 with it. A free end 305a of the beam is curved downwards, driving a part of the zone 123 of the membrane 2 with it, which is linked to the beam 305. By preservation of volume, the free zone 121 of the membrane 12 is itself moved upwards, thus driving the movement upwards of the pin 122 with it. This scenario corresponds to that illustrated in FIG. 1A. Another end 305b of the beam 302 preferably remains fixed. This other end 305b, is for example, integral with a fixed wall of the cavity 13, which is constituted of the spacer 306 and/or of the lateral abutment 15 located facing one another. In this sense, it can be provided that the lateral abutment 15 forms all or some of a cap of the electromechanical microsystem 1, the cap having the role of ensuring the engagement of the end 305b of the beam 302.

In FIG. 2B, the piezoelectric material 302 is located above the beam 305, i.e. that the beam 305 is located between the piezoelectric material 302 and the membrane 12. When a voltage is applied on the piezoelectric material 302, it is retracted and drives the beam 305 with it. A free end 305a of the beam thus bends upwards, pulling a part of the zone 123 of the membrane 12 with it, which is linked to the beam 305. By preservation of volume, the free zone 121 of the membrane is itself moved downwards, thus driving the movement downwards of the pin 122 with it. This scenario corresponds to that illustrated in FIG. 1B.

The different heights that the pin 122 can have relative to the height of the lateral abutments 15 are also observed in FIGS. 2A and 2B. There, it is only also observed that the lateral abutments 15 and the bottom abutments 16, and/or their cross-section, can take different shapes, and in particular a parallelepiped shape, a truncated shape, a substantially pyramidal shape, etc.

It is further observed, in FIGS. 2A and 2B, that the moveable part 111 of the electromechanical transducer 11 can be defined by the extent of the piezoelectric material 302 relative to the extent of the beam 305.

In FIGS. 2A and 2B, access openings for an electrical connection of the electrodes are represented. These openings form vias 17 in these examples. In this example, the vias 17 pass through the whole thickness of the beam 305 and the whole thickness between the lateral abutments 15. In this case, it is noted that the lateral abutments such as illustrated in FIGS. 2A and 2B can each form a ring and conserve a via 17 between them, itself taking the shape of a ring; alternatively, the lateral abutments 15 can also only form one single ring in the thickness of which at least one via 17, for example cylindrically-shaped, would be formed. The thickness e₃₀₅ of the beam 302 is measured in a direction perpendicular to the plane, wherein the faces 12e and 12i of the membrane 12 mainly extend at rest. The thickness e₃₀₅ is referenced in FIGS. 2A and 2B.

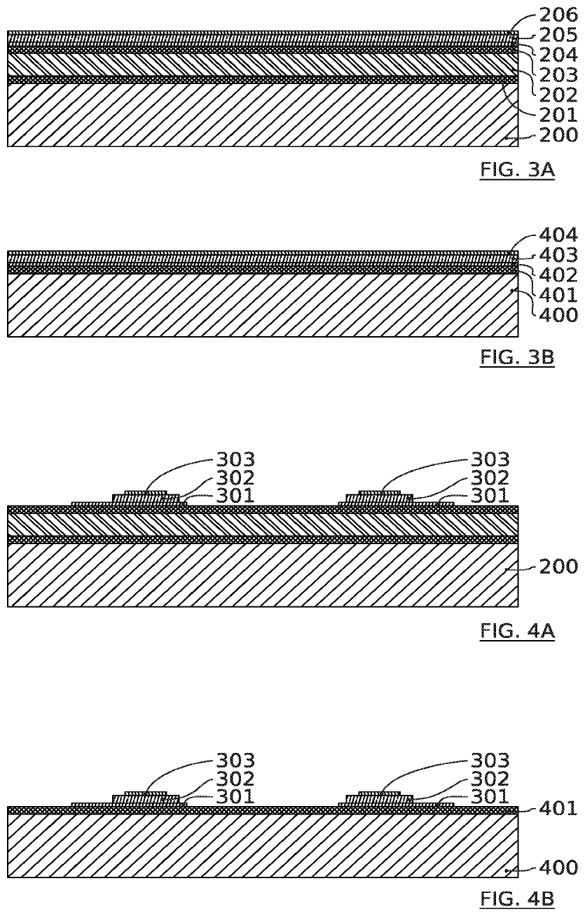

FIGS. 2A and 2B illustrate more specifically, third and fourth embodiments of the invention which have been obtained by etching and deposition steps which could be qualified as ordinary in the microelectronics field. More specifically, the electromechanical microsystem 1 according to the third embodiment illustrated in FIG. 2A has been obtained by the succession of steps illustrated by FIGS. 3A, 4A, 5A, 6A, 7A, 8A and 9A and the electromechanical microsystem 1 according to the fourth embodiment illustrated in FIG. 2B has been obtained by the succession of steps illustrated by FIGS. 3B, 4B, 5B, 6B, 7B, 8B and 9B. Thus, two manufacturing methods are illustrated, which each lead to one of the electromechanical microsystems 1 illustrated in FIGS. 2A and 2B.

These manufacturing methods have, at least in common, to comprise:
a. a formation step from which is intended to constitute at least one portion of the electromechanical transducer 11 on a substrate 200, then
b. a step of depositing the deformable membrane 12, then
c. a step of forming a cavity 13 open on the deformable membrane 13, then
d. a step of filling with the deformable medium and of closing the cavity 13, and
e. a step of etching the substrate 200 to form the front face of the electromechanical microsystems illustrated in FIGS. 2A and 2B.

Below, successively each of the abovementioned manufacturing methods are described, starting with the method for manufacturing the electromechanical microsystem 1 such as illustrated in FIG. 2A.

The first step of this method is illustrated in FIG. 3A. It consists of providing a substrate 200 on which a stack of layers extends, which can successively comprise, from a face of the substrate 200:
a. a first insulating layer 201, for example silicon oxide-based, which could be deposited by plasma-enhanced chemical vapour deposition (PECVD),
b. a layer 202 intended to constitute the beam 305 of the electromechanical transducer 11, this layer 202 being, for example, amorphous, polycrystalline or monocrystalline silicon-based, and which could be deposited by chemical vapour deposition (CVD), or low pressure chemical vapour deposition (LPCVD), or by using an SOI (silicon on insulator)-type structure,
c. a second insulating layer 203, for example, silicon oxide-based, and which could be deposited by PECVD,
d. a layer 204 intended to constitute a so-called lower electrode, for example platinum-based and which could be deposited by physical vapour deposition (PVD),
e. a layer 205 made of a piezoelectric material, for example PZT-based, and which could be deposited by a sol-gel method, and
f. a layer 206 intended to constitute a so-called upper electrode, for example platinum-based and which could be deposited by PVD.

The second step of the method for manufacturing the electromechanical microsystem 1 such as illustrated in FIG. 2A is illustrated in FIG. 4A. It comprises:
a. an etching of the layer 206, so as to form the upper electrode 301 of the electromechanical transducer 11,
b. an etching of the layer 205, so as to form the piezoelectric elements 302 of the electromechanical transducer 11, and
c. an etching of the layer 204, so as to form the lower electrode 303 of the electromechanical transducer 11.

It is noted that each of these etchings can be done by lithography, and preferably by plasma etching, or by wet chemical etching.

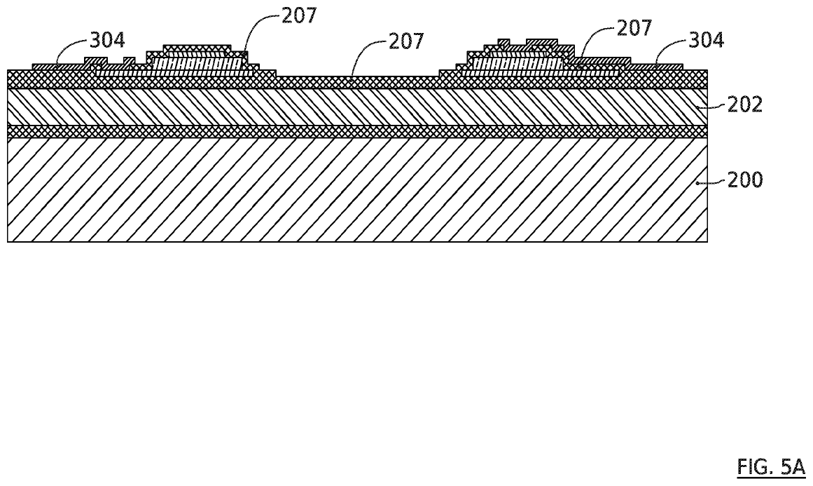

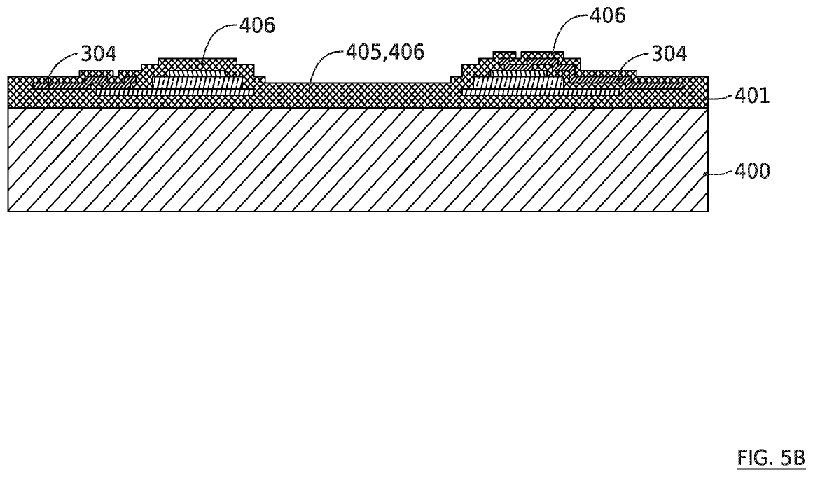

The third step of the method for manufacturing the electromechanical microsystem 1 such as illustrated in FIG. 2A is illustrated in FIG. 5A. It comprises:
a. the deposition of a passivation layer 207, for example silicon oxide- and/or silicon nitride-based, which could be deposited by PECVD,
b. the opening, through the passivation layer 207, of an electrode contact zone, this opening being achieved, for example, by lithography, and preferably by plasma etching, or by wet chemical etching,
c. the deposition of a layer intended to constitute one electrical line 304 per electrode, the layer being, for example, gold-based, and which could be deposited by PVD, and
d. an etching of the layer previously deposited so as to form one electrical line 304 per electrode, this etching being done, for example, by lithography, and preferably by plasma etching, or by wet chemical etching.

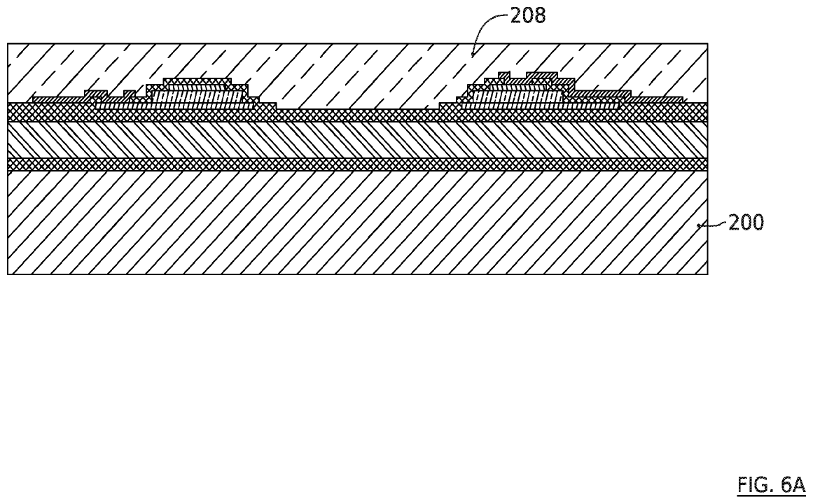

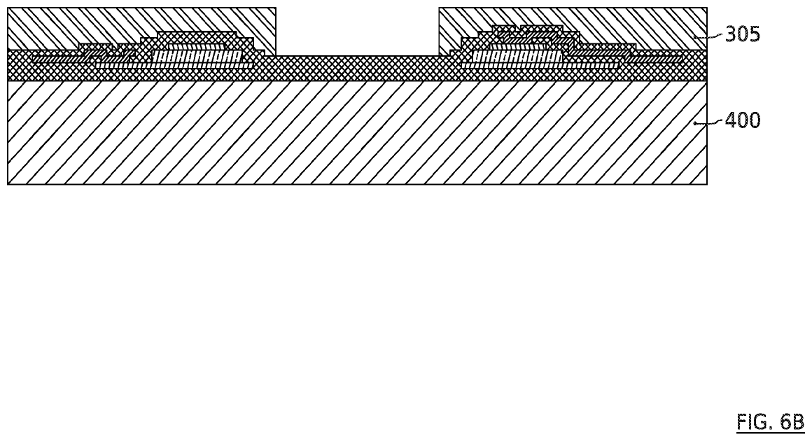

The fourth step of the method for manufacturing the electromechanical microsystem 1 such as illustrated in FIG. 2A is illustrated in FIG. 6A. It comprises the deposition of a layer 208 with the basis of a polymer and intended to constitute the deformable membrane 12. This layer 208 is, for example, deposited by spin coating. The polymer with the basis of which the layer 208 is constituted is, for example, PDMS-based.

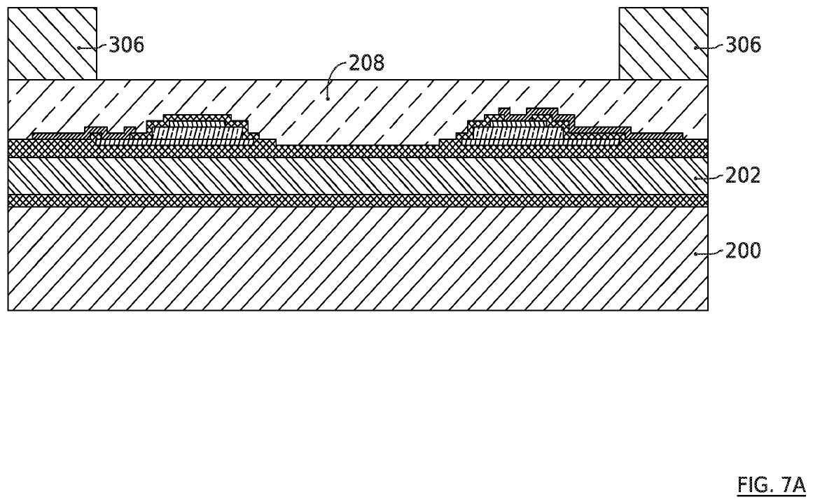

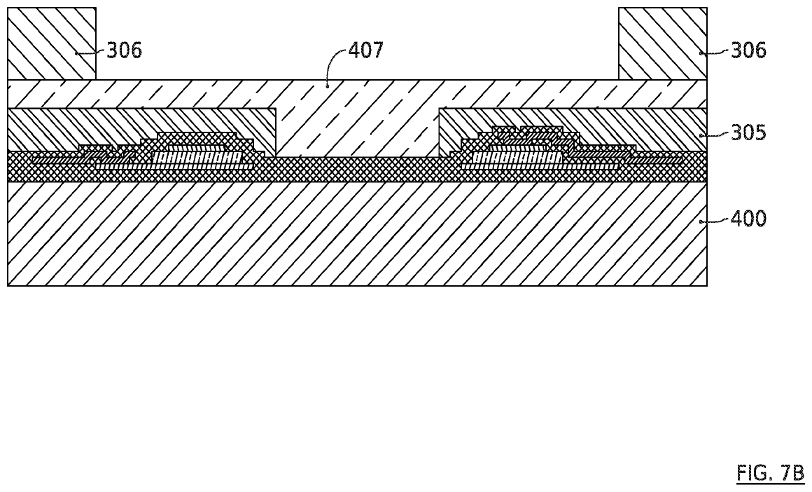

The fifth step of the method for manufacturing the electromechanical microsystem 1 such as illustrated in FIG. 2A is illustrated in FIG. 7A. It comprises the formation of at least one spacer 306 intended to constitute at least one part of said at least one side wall 133 of the cavity 13. The formation of the spacer(s) can comprise the lamination of a photosensitive material with the basis of which the spacer(s) is/are constituted, the insulation, then the development of the photosensitive material. Said photosensitive material can be with the basis of a polymer, and in particular siloxane-based. The lamination of the photosensitive material can comprise the lamination of a dry film of said material.

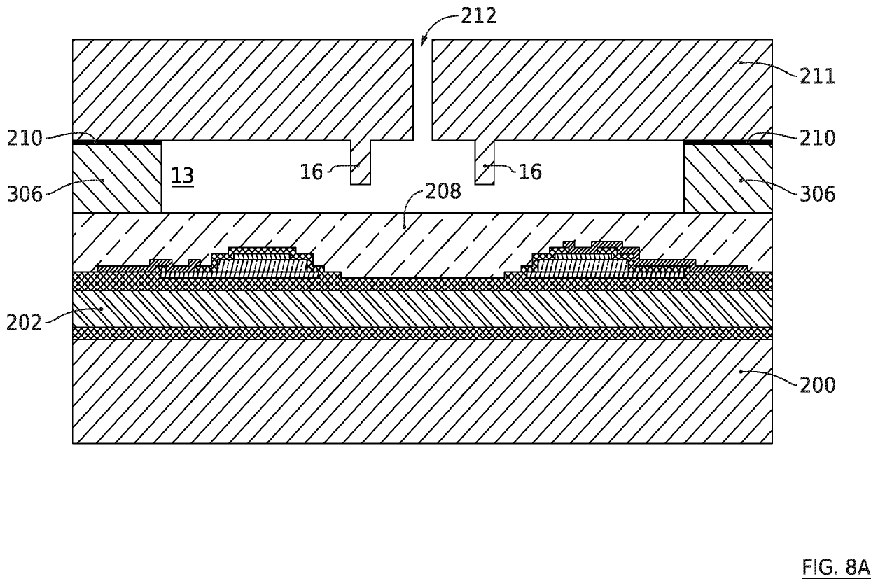

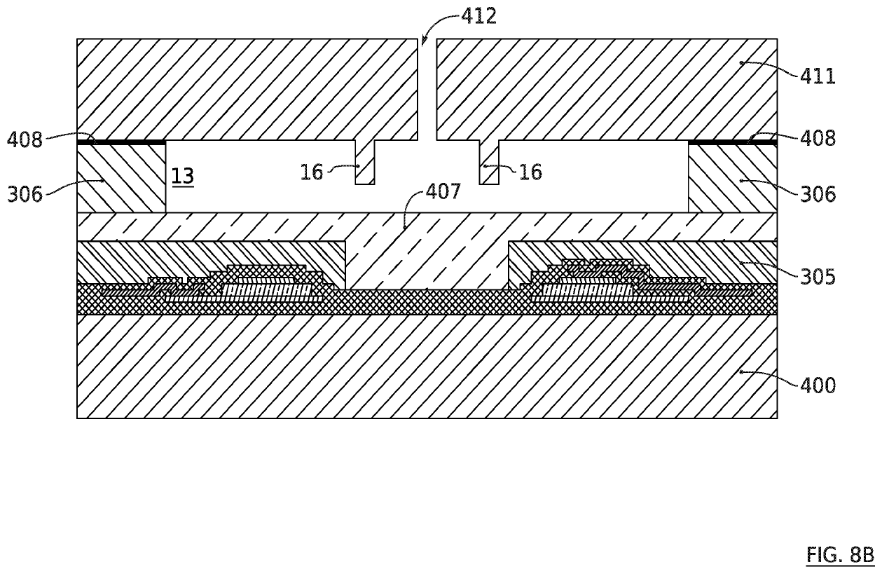

The sixth step of the method for manufacturing the electromechanical microsystem 1 such as illustrated in FIG. 2A is illustrated in FIG. 8A. According to an optional embodiment, this step comprises the deposition of glue 210 at the top of each spacer 306, this deposition could be done by screen printing or by dispensation. It comprises the fixing, for example the bonding, on the top of the spacer(s) (optionally by way of glue 210), of a second substrate 211 which could be structured so as to comprise at least one from among a through vent 212 and a bottom abutment 16, such as described above. In an alternative embodiment, according to the nature of the spacer, this can play the role of glue. Coming from this sixth step, the cavity 13 is formed which is open by at least one through vent 212.

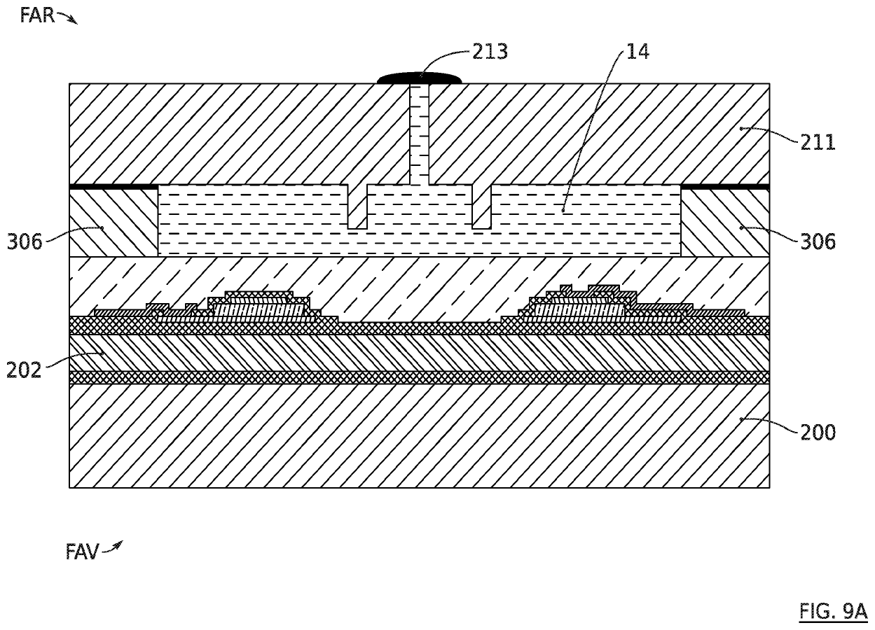

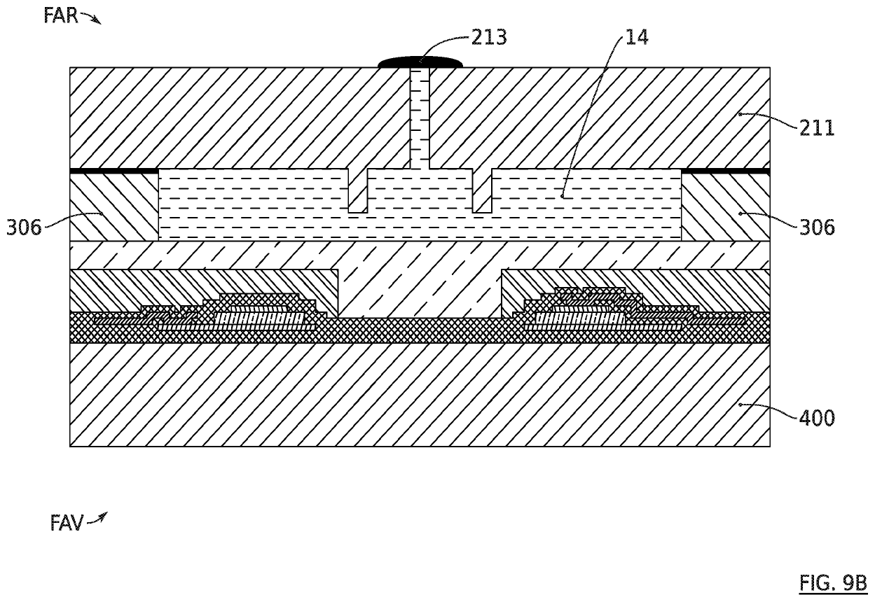

The seventh step of the method for manufacturing the electromechanical microsystem 1 such as illustrated in FIG. 2A is illustrated in FIG. 9A. It comprises the filling, preferably under vacuum, of the cavity 13 with the deformable medium 14 such as described above, for example by dispensation through the through vent 212. It also comprises the sealed closing of the through vent 212, for example by dispensation of a sealing material 213 at the mouth of each through vent 212, the sealing material 213 being, for example, with the basis of an epoxy glue.

An additional step makes it possible to obtain the electromechanical microsystem 1 such as illustrated in FIG. 2A. It comprises the etching of the substrate 200, then the etching of the layer 202 and of the insulating layers 201, 203, so as to form at least one beam 305 of the electromechanical transducer 11, to expose a part of the deformable membrane 12 and to constitute all or some of the pin 122 and optional lateral abutments 15. This additional step can be carried out by lithography, and preferably by plasma etching, or by wet chemical etching.

It is noted that, following the steps described above of manufacturing the electromechanical microsystem 1, such as illustrated in FIG. 2A, the pin 122 takes the form of a stack extending directly from the deformable membrane 12 opposite the cavity 13 by successively having the material of the insulating layer 201, the material constituting the beam 305, the material of the insulating layer 203 and the material constituting the substrate 200. It is also noted that, following the steps described above of manufacturing the electromechanical microsystem 1, such as illustrated in FIG. 2A, the optional lateral abutments 15 each take the form of a stack extending, directly or indirectly, from the deformable membrane 12 opposite the cavity 13 by successively having the material of the insulating layer 201, the material constituting the beam 305, the material of the insulating layer 203 and the material constituting the substrate 200.

The method for manufacturing the electromechanical microsystem 1, such as illustrated in FIG. 2B is described below.

The first step of this method is illustrated in FIG. 3B. It consists of providing a substrate 400 on which a stack of layers extends which can successively comprise, from a face of the substrate 400:
a. a first insulating layer 401, for example, silicon oxide-based, which could be deposited by plasma-enhanced chemical vapour deposition (PECVD),
b. a layer 402 intended to constitute a so-called lower electrode, for example platinum-based and which could be deposited by PVD,
c. a layer 403 made of a piezoelectric material, for example PZT-based, and could be deposited by a sol-gel method, and
d. a layer 404 intended to constitute a so-called upper electrode, for example platinum-based and which could be deposited by PVD.

The second step of the method for manufacturing the electromechanical microsystem 1, such as illustrated in FIG. 2B is illustrated in FIG. 4B. It comprises:
a. an etching of the layer 404 so as to form the upper electrode 301 of the electromechanical transducer 11,
b. an etching of the layer 403 so as to form the piezoelectric elements 302 of the electromechanical transducer 11, and
c. an etching of the layer 402 so as to form the lower electrode 303 of the electromechanical transducer 11.

It is noted that each of these etchings can be done by lithography, and preferably by plasma etching, or by wet chemical etching.

The third step of the method for manufacturing the electromechanical microsystem 1, such as illustrated in FIG. 2B is illustrated in FIG. 5B. It comprises:
a. the deposition of a passivation layer 405, for example, silicon oxide- and/or silicon nitride-based, which could be deposited by PECVD,
b. the opening, through the passivation layer 405, of an electrode contact zone, this opening being achieved, for example, by lithography, and preferably by plasma etching, or by wet chemical etching,
c. the deposition of a layer intended to constitute one electrical line 304 per electrode, the layer being, for example, gold-based and which could be deposited by PVD,
d. an etching of the layer previously deposited, so as to form one electrical line 304 per electrode, this etching being done, for example, by lithography, and preferably by plasma etching, or by wet chemical etching, then
e. the deposition of a passivation layer 406, for example, silicon oxide- and/or silicon nitride-based, which could be deposited by PECVD.

The fourth step of the method for manufacturing the electromechanical microsystem 1, such as illustrated in FIG. 2B is illustrated in FIG. 6B. It comprises the deposition of a layer intended to constitute the beam 305 of the electromechanical transducer 11, this layer being, for example, amorphous silicon-based and could be deposited by PVD. It can then comprise a step of flattening the layer previously deposited. It then comprises an etching of the layer previously deposited so as to form at least one beam 305 of the electromechanical transducer 11. This etching being done, for example, by lithography, and preferably by plasma etching, or by wet chemical etching.

The fifth step of the method for manufacturing the electromechanical microsystem 1, such as illustrated in FIG. 2B is illustrated in FIG. 7B. It comprises:
a. the deposition of a layer 407 with the basis of a polymer and intended to constitute the deformable membrane 12; this layer 407 is, for example, deposited by spin coating. The polymer with the basis of which the layer 407 is constituted, is, for example, PDMS-based, and
b. the formation of at least one spacer 306 intended to constitute at least one part of said at least one side wall 133 of the cavity 13.

The formation of the spacer(s) 306 can comprise the lamination of a photosensitive material with the basis of which the spacer(s) is/are constituted, the insolation, then the development of the photosensitive material. Said photosensitive material can be with the basis of a polymer, and in particular, siloxane-based. The lamination of the photosensitive material can comprise the lamination of a dry film of said material.

The sixth step of the method for manufacturing the electromechanical microsystem 1, such as illustrated in FIG. 2B is illustrated in FIG. 8B. It comprises, if necessary, the deposition of glue 408 at the top of each spacer 306. According to an optional example, this deposition can be done by screen printing or by dispensation. It comprises the bonding, on the top of the spacer(s) 306 (optionally by way of the glue 408), of a second substrate 411 which could be structured, so as to comprise at least one from among a through vent 412 and a bottom abutment 16, such as described above. In an alternative embodiment, according to the nature of the spacer, this can play the role of glue. Coming from this sixth step, the cavity 13 is formed which is open by at least one through vent 412.

The seventh step of the method for manufacturing the electromechanical microsystem 1, such as illustrated in FIG. 2B is illustrated in FIG. 9B. It comprises the filling, preferably under vacuum, of the cavity 13 with the deformable medium 14, such as described above, for example, by dispensation through the at least one through vent 212. It also comprises the sealed closing of the at least one through vent 212, for example, by dispensation of a sealing material 213 at least at the mouth of each through vent 212, the sealing material 213 being, for example, with the basis of an epoxy glue.

An additional step makes it possible to obtain the electromechanical microsystem 1, such as illustrated in FIG. 2B. It comprises the etching of the substrate 400, then the etching of the insulating layer 401, so as to expose a part of the deformable membrane 12 and to constitute all or some of the pin 122, and optional lateral abutments 15. This additional step can be carried out by lithography, and preferably by plasma etching, or by wet chemical etching.

It is noted that, following the steps described above of manufacturing the electromechanical microsystem 1, such as illustrated in FIG. 2B, the pin 122 takes the form of a stack extending directly from the deformable membrane 12 opposite the cavity 13 by successively having the material of the insulating layer 401 and the material constituting the substrate 400. It is also noted that, following the steps described above of manufacturing the electromechanical microsystem 1, such as illustrated in FIG. 2B, the optional lateral abutments 15 each take the form of a stack extending, directly or indirectly, from the beam 305 opposite the cavity 13 by successively having the material of the insulating layer 401 and the material constituting the substrate 400.

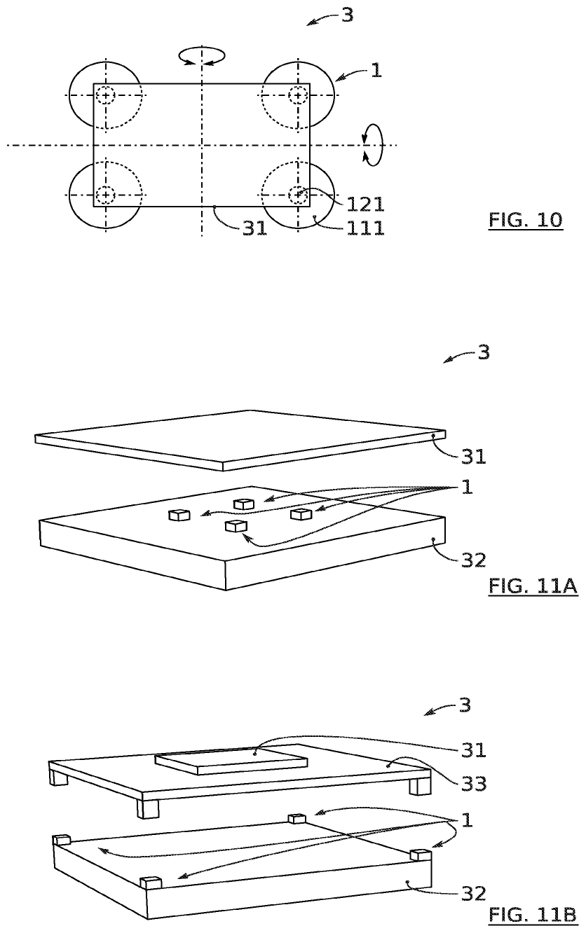

Another aspect of the invention relates to an opto-electromechanical system 3, such as illustrated in FIGS. 10, 11A and 11B. This can be an opto-electromechanical microsystem 3. Each of the opto-electromechanical microsystems 3 illustrated in these figures comprises at least one electromechanical microsystem 1, such as described above and at least one optical microsystem 31. Said at least one electromechanical microsystem 1 is preferably mounted on a support 32 of the opto-electromechanical microsystem 3. Said at least one optical microsystem 31 can comprise a silicon-based micro-mirror, the surface of which is, if necessary, surmounted by at least one mirror. It can be mounted directly on said at least one electromechanical microsystem 1, or be mounted there by way of a frame 33. It can have dimensions substantially equal to 2 mm×5 mm and/or, as a maximum, a thickness of around 700 μm. The opto-electromechanical microsystems 3, such as illustrated, each comprise four electromechanical microsystems 1, each having a free zone 121 arranged opposite a part of one same optical microsystem 31. Thus, an opto-electromechanical microsystem 1 is obtained, benefiting from a wide capacity to adapt its optical orientation.

The invention is not limited to the embodiments described above, and extends to all the embodiments covered by the claims.

In particular, applications other than those described above can be considered. For example, the electromechanical microsystem 1 can be arranged in a micropump, even in a micropump table system, in a haptic system.

1. An electromechanical microsystem, comprising:
at least one electromechanical transducer comprising a moveable part between a non-urged balanced position, and an urged unbalanced position,
at least one deformable membrane,
a deformable cavity, delimited by walls, at least one part of the deformable membrane forming at least one part of a first wall taken among said walls of the cavity, the cavity hermetically containing a deformable medium preserving a substantially constant volume under action of an external pressure change exerted on the deformable medium through a wall of the walls of the cavity,
wherein the moveable part of the electromechanical transducer is configured such that movement is a function of said external pressure change, or conversely that the movement induces an external pressure change,
wherein said at least one part of the deformable membrane has a free zone to be deformed, according to said external pressure change,
wherein said free zone is configured to engage with an external member such that its deformation of the free zone induces, or is induced by, a movement of the external member, and
wherein a surface of the free zone of the deformable membrane is twice lower than a surface of the moveable part of the electromechanical transducer.

2. The electromechanical microsystem according to claim 1, wherein the free zone of the deformable membrane is configured to engage with the external member via a pin fixed on said free zone, in contact with said free zone.

3. The electromechanical microsystem according to claim 2, wherein the pin is formed at a same time as the free zone of the deformable membrane is exposed.

4. The electromechanical microsystem according to claim 2, wherein the pin is fixed to the center of the free zone of the deformable membrane.

5. The electromechanical microsystem according to claim 2, wherein the pin is configured to be able to be integral with the external member by bonding or magnetism.

6. The electromechanical microsystem according to claim 1, wherein at least one part of the electromechanical transducer forms a part of said first wall of the cavity.

7. The electromechanical microsystem according to claim 6, wherein the electromechanical transducer extends, directly or indirectly, on the deformable membrane, and around the free zone of the deformable membrane.

8. The electromechanical microsystem according to the claim 7, wherein the electromechanical transducer fully surrounds the free zone of the deformable membrane, the electromechanical transducer having an annular shape, the circular centre center of which defines the extent of the free zone of the deformable membrane.

9. The electromechanical microsystem according to claim 1, wherein the electromechanical transducer is configured, such that a movement of the moveable part from a balanced position to an unbalanced position induces an increase of the external pressure acting on the deformable medium, and wherein the deformable membrane is configured such that an increase of the external pressure acting on the deformable medium induces a deformation of the free zone of the deformable membrane tending to move the external member of at least one second wall of the cavity away, the second wall being different from the first wall and remaining fixed, when the deformable membrane is deformed.

10. The electromechanical microsystem according to claim 1, wherein the electromechanical transducer is configured such that a movement of the moveable part from an balanced position to its unbalanced position induces a decrease of the external pressure acting on the deformable medium and wherein the deformable membrane is configured such that a decrease of the external pressure acting on the deformable medium induces a deformation of the free zone of the deformable zone, tending to move the external member of at least one second wall of the cavity closer, the second wall being different from the first wall and remaining fixed when the deformable membrane is deformed.

11. The electromechanical microsystem according to claim 1, wherein at least the moveable part of the electromechanical transducer is integral with a zone of the deformable membrane adjacent to the free zone of the deformable membrane, such that a movement of the moveable part of the electromechanical transducer induces a corresponding movement of said zone of the deformable membrane adjacent to its free zone.

12. The electromechanical microsystem according to claim 1, wherein the moveable part of the electromechanical transducer has a surface at least twice larger than a surface of the free zone of the deformable membrane.

13. The electromechanical microsystem according to claim 1, wherein the deformable membrane is configured such that its free zone is capable of being deformed with an amplitude of at least 50 μm in a direction perpendicular to the plane, wherein the membrane mainly extends when at rest.

14. The electromechanical microsystem according to claim 1, further comprising at least one lateral abutment, supported by said first wall of the cavity, configured to guide the movement of the external member.

15. The electromechanical microsystem according to claim 14, wherein, the free zone of the deformable membrane is configured to engage with the external member via a pin fixed on said free zone, the pin extends from the free zone of the deformable membrane beyond said at least one lateral abutment.

16. The electromechanical microsystem according to claim 14, wherein, the free zone of the deformable membrane is configured to engage with the external member via a pin fixed on said free zone, the pin extends from the free zone of the deformable membrane below said lateral abutment.

17. The electromechanical microsystem according to claim 1, further comprising a bottom abutment supported by the wall of the cavity opposite the free zone of the deformable membrane, the bottom abutment extending into the cavity towards the free zone and having a shape and dimensions configured to limit the deformation of the free zone of the deformable membrane or limit the contact surface between the membrane and the wall of the cavity opposite the free zone of the deformable membrane.

18. The electromechanical microsystem according to claim 1, wherein the electromechanical transducer is a piezoelectric transducer, comprising a PZT-based piezoelectric material.

19. The electromechanical microsystem according to claim 1, wherein the electromechanical transducer is a static working transducer.

20. The electromechanical microsystem according to claim 1, wherein the electromechanical transducer is a vibration working transducer at at least one resonance frequency, said at least one resonance frequency being less than 100 kHz.

21. The electromechanical microsystem according to claim 1, wherein the deformable medium hermetically contained in the cavity comprises at least one fluid.

22. An opto-mechanical system comprising at least one electromechanical microsystem according to claim 1, and at least one optical microsystem.

23. The opto-mechanical system according to claim 22, wherein said at least one optical microsystem comprises at least one mirror, the opto-electromechanical system being configured such that the movement of the moveable part of the electromechanical transducer causes a movement of the at least one mirror.

24. The opto-mechanical system according to claim 22, further comprising a plurality of the electromechanical microsystems, each having a free zone arranged opposite a part of one same optical microsystem.

25. A method for manufacturing an electromechanical microsystem according to claim 1, the method comprising:
forming, on a substrate, at least one portion of at least one electromechanical transducer,
depositing the deformable membrane,
forming a cavity open on the deformable membrane,
filling with the deformable medium and closing the cavity, and
etching the substrate to form a front face of the electromechanical microsystem.
